(19) United States
(12) Patent Application Publication
(10) Pub. No.: US 2024/0234439 A9
(43) Pub. Date: Jul. 11, 2024

(54) DISPLAY PANEL AND DISPLAY DEVICE

(71) Applicant: Shanghai Tianma Microelectronics Co., Ltd., Shanghai (CN)

(72) Inventors: Tenggang LOU, Shanghai (CN); Qiongqin MAO, Shanghai (CN)

(73) Assignee: Shanghai Tianma Microelectronics Co., Ltd., Shanghai (CN)

(21) Appl. No.: 18/403,852

(22) Filed: Jan. 4, 2024

(30) Foreign Application Priority Data
Aug. 28, 2023 (CN) 202311095417.6

(51) Int. Cl. H01L 27/12; G02F 1/1333

(52) U.S. Cl. CPC H01L 27/124; G02F 1/133382

(57) ABSTRACT

Provided are a display panel and a display device. The display panel includes a display region and a non-display region. At least part of the non-display region is configured to be attached to a backlight module. The display panel also includes multiple heating wires located in the display region and the non-display region. In the same area, the resistance of heating wires located in the non-display region is higher than the resistance of heating wires located in the display region.

### CROSS-REFERENCE TO RELATED APPLICATION

This application claims priority to Chinese Patent Application No. CN 202311095417.6, filed on Aug. 28, 2023, the disclosure of which is incorporated herein by reference in its entirety.

### TECHNICAL FIELD

Embodiments of the present application relate to the field of display technology and, in particular, to a display panel and a display device.

### BACKGROUND

In some particular usage fields of a display device, the display device is required to be suitable to a wide range of ambient temperatures. A liquid crystal display device is used as an example. Since the viscosity coefficient of a liquid crystal material increases at low temperatures, the threshold voltage increases, the response speed becomes slow, and even a liquid crystal crystallization phenomenon occurs, the liquid crystal display device cannot work normally. In the related art, to ensure that a display device works normally at low temperatures, a heating structure is generally disposed in the display device, and the display device is heated by the heating structure. However, in the related art, there is still a problem that the heating effect of a display device is not ideal.

### SUMMARY

In view of the above, the present application provides a display panel and a display device to enhance the heating effect on the edge region of the display panel and ensure the consistency of the temperature of each region of the display panel.

In a first aspect, an embodiment of the present application provides a display panel. The display panel includes a display region and a non-display region. At least part of the non-display region is configured to be attached to a backlight module.

The display panel also includes multiple heating wires located in the display region and the non-display region. In the same area, the resistance of heating wires located in the non-display region is higher than the resistance of heating wires located in the display region.

In a second aspect, an embodiment of the present application provides a display device. The display device includes the display panel described in the first aspect of the present application and a backlight module. The backlight module is located on the side of the display panel facing away from the light-emitting side of the display panel.

In embodiments of the present application, the display panel includes a display region and a non-display region. At least part of the non-display region is configured to be attached to the backlight module. The display panel also includes multiple heating wires located in the display region and the non-display region. In the same area, the resistance of the heating wires located in the non-display region is higher than the resistance of the heating wires located in the display region. In the technical solutions of the present application, the heating wires may heat the display region and the non-display region of the display panel to ensure the overall heating effect of the display panel. In addition, it is also possible to enhance the heating effect of the non-display region of the display panel to make up for the problem of fast heat dissipation of the non-display region. In this manner, the temperatures of the display region and the non-display region of the display panel are relatively consistent. Thus, the normal application of the display panel is ensured, and the reliability of the display panel is improved.

### BRIEF DESCRIPTION OF DRAWINGS

FIG. 1 is a sectional view illustrating the structure of a display device in the related art.

FIG. 2 is a top view illustrating the structure of a display panel in the related art.

FIG. 3 is an enlarged view illustrating the structure of part A of FIG. 2.

FIG. 4 is a sectional view illustrating the structure of a display device according to an embodiment of the present application.

FIG. 5 is a top view illustrating the structure of a display panel according to an embodiment of the present application.

FIG. 6 is an enlarged view illustrating the structure of part B of FIG. 5.

FIG. 7 is an enlarged view illustrating another structure of part B of FIG. 5.

FIGS. 8 and 9 are two enlarged partial views illustrating the structures of two display panels at part C of FIG. 5.

FIG. 10 is an enlarged partial view illustrating the structure of a display panel according to an embodiment of the present application.

FIG. 11 is an enlarged partial view illustrating the structure of another display panel according to an embodiment of the present application.

FIG. 12 is an enlarged partial view illustrating the structure of another display panel according to an embodiment of the present application.

FIG. 13 is an enlarged partial view illustrating the structure of another display panel according to an embodiment of the present application.

FIG. 14 is an enlarged partial view illustrating the structure of another display panel according to an embodiment of the present application.

FIG. 15 is an enlarged partial view illustrating the structure of another display panel according to an embodiment of the present application.

FIG. 16 is an enlarged view illustrating the structure of part D of FIG. 5.

FIGS. 17 and 18 are another two enlarged partial views illustrating the structures of a display panel according to an embodiment of the present application.

FIG. 19 is an enlarged partial view illustrating the structure of another display panel according to an embodiment of the present application.

FIG. 20 is an enlarged partial view illustrating the structure of another display panel according to an embodiment of the present application.

FIG. 21 is a diagram illustrating the structure of another display panel according to an embodiment of the present application.

FIG. 22 is a sectional view illustrating the structure of a display panel according to an embodiment of the present application.

FIG. 23 is an enlarged partial view illustrating the structure of another display panel according to an embodiment of the present application.

FIG. 24 is a top view illustrating the structure of a display device according to an embodiment of the present application.

### DETAILED DESCRIPTION

Hereinafter the present application is further described in detail in conjunction with the drawings and embodiments. It is to be understood that the specific embodiments described herein are intended to illustrate and not to limit the present application. Additionally, it is to be noted that, for ease of description, only part, not all, of structures related to the present application are illustrated in the drawings.

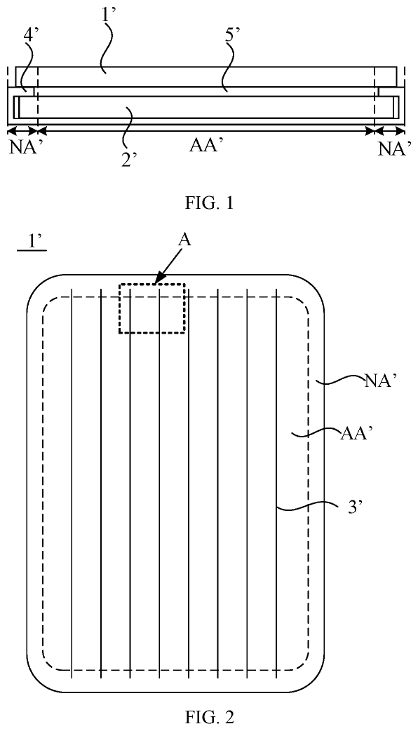

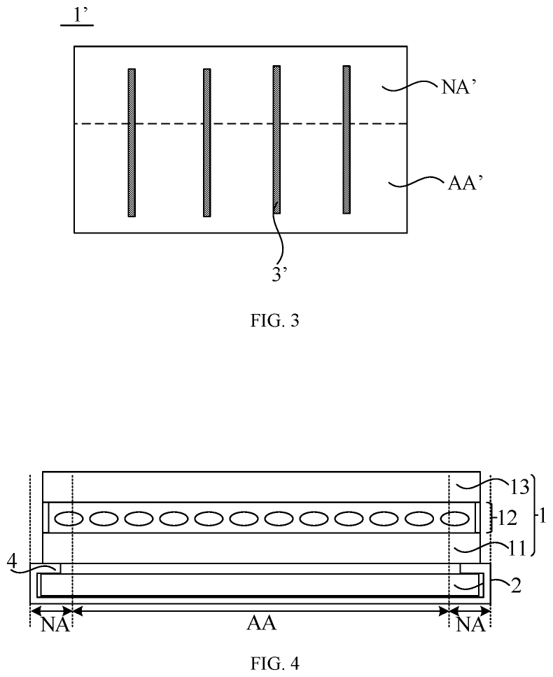

FIG. 1 is a sectional view illustrating the structure of a display device in the related art. FIG. 2 is a top view illustrating the structure of a display panel in the related art. FIG. 3 is an enlarged view illustrating the structure of part A of FIG. 2. As shown in FIGS. 1 to 3, the surface of a side of a display panel 1′ is fixed to a backlight module 2′ to form a display device. To heat the display panel 1′, in the related art, heating wires 3′ are disposed in the display panel 1′. Referring to FIGS. 2 and 3, in the related art, the structures of heating wires 3′ located in a display region AA′ and the structures of heating wires 3′ located in a non-display region NA′ are exactly the same. In the same area, the heating effects of heating wires 3′ on the display region AA′ and the non-display region NA′ are the same. However, the inventor finds that at the initial stage of heating, the display effect of the center of the display region AA′ and the display effect of the edge of the display region AA′ in an actual product are different, and it is apparent that the display effect of the edge of the display region AA′ is relatively poor. Through analysis, the inventor finds that although the heating wires 3′ are disposed in the non-display region NA′ so that the heating environment of the edge pixels of the display region AA′ is consistent with the heating environment of the middle pixels of the display region AA′, due to fast heat dissipation at the edge of the display panel 1′, the actual heating environment of the edge pixels of the display region AA′ is changed. The inventor continues further research and finds that the edge of the display panel 1′ is in contact with the backlight module 2′. There is an air layer 5′ between the middle region of the display panel 1′ and the backlight module 2′. Since the thermal conductivity of the backlight module 2′ is higher than the thermal conductivity of air, heat dissipation is faster at the edge. Specifically, referring to FIG. 1, description is given by using an example of an assembly structure of the display device. In some cases, the edge of the display panel 1′ is fixed to the middle frame 4′ of the backlight module 2′. The middle frame 4′ is generally made of metal. The thermal conductivity of the middle frame 4′ is higher than the thermal conductivity of the air layer 5′ in the middle region of the display panel 1′, so that the heat dissipation speed at the edge of the display panel 1′ is faster than the heat dissipation speed of the display region AA′. In the solutions of the related art, a better heating effect on the edge region of the display panel 1′ cannot be implemented. As a result, there is a temperature difference between the display region of the display panel 1′ and the non-display region NA′ at the edge, and the performance of the liquid crystal material and/or other devices adjacent to the edge of the display panel 1′ is affected. Furthermore, the reliability of the display panel 1′ is affected.

Based on the above-mentioned drawbacks of the related art, the inventor proposes the technical solutions in the present application. In an embodiment, the present application provides a display panel. The display panel includes a display region and a non-display region. At least part of the non-display region is configured to be attached to a backlight module.

The display panel also includes multiple heating wires located in the display region and the non-display region. In the same area, the resistance of heating wires located in the non-display region is higher than the resistance of heating wires located in the display region.

In the preceding technical solutions, the heating wires may heat the display region and the non-display region of the display panel to ensure the overall heating effect of the display panel. In addition, it is also possible to enhance the heating effect of the non-display region of the display panel to make up for the problem of fast heat dissipation of the non-display region. In this manner, the temperatures of the display region and the non-display region of the display panel are relatively consistent. Thus, the normal application of the display panel is ensured, and the reliability of the display panel is improved.

The above is the core concept of the present application, and the technical solutions in the embodiments of the present application are described clearly and completely hereinafter in conjunction with the drawings in the embodiments of the present application. Based on the embodiments of the present application, all other embodiments obtained by those of ordinary skill in the art without creative work are within the scope of the present application.

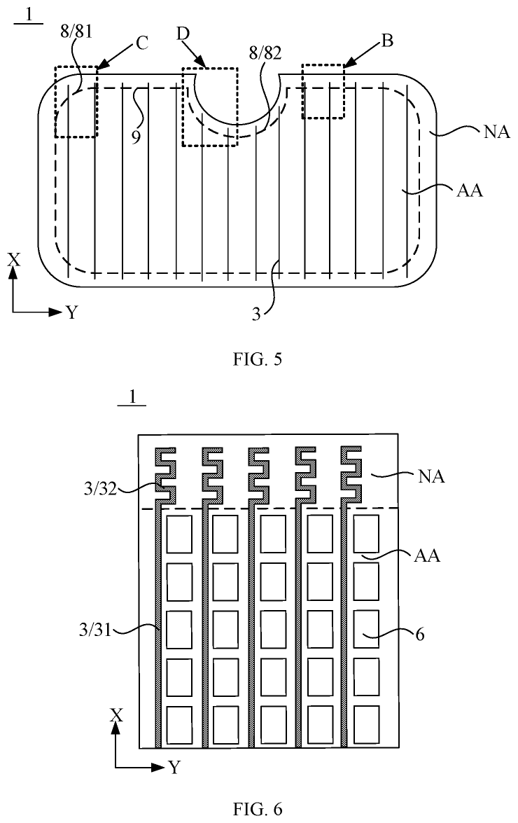

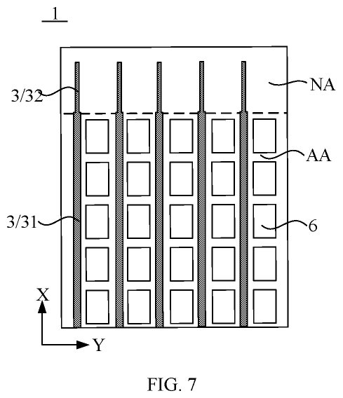

FIG. 4 is a sectional view illustrating the structure of a display device according to an embodiment of the present application. FIG. 5 is a top view illustrating the structure of a display panel according to an embodiment of the present application. FIG. 6 is an enlarged view illustrating the structure of part B of FIG. 5. Referring to FIGS. 4 to 6, in this embodiment of the present application, a display panel 1 includes a display region AA and a non-display region NA. At least part of the non-display region NA is configured to be attached to a backlight module 22. The display panel 1 also includes multiple heating wires 3 located in the display region AA and the non-display region NA. In the same area, the resistance of heating wires 3 located in the non-display region NA is higher than the resistance of heating wires 3 located in the display region AA.

In an embodiment, as shown in FIGS. 4 to 6, at least part of the non-display region NA on the side of the display panel 1 facing the backlight module 2 is fixed to the middle frame 4 of the backlight module 2. The heating wires 3 in the display panel 1 are disposed in both the display region AA and the non-display region NA to heat the display region AA and the non-display region of the display panel 1 to ensure the heating effect of the non-display region NA in the display panel 1.

In addition, further referring to FIGS. 4 to 6, in view of the relatively fast rate of heat dissipation at the joint between the non-display region NA of the display panel 1 and the backlight module 2, in this embodiment, the heating wires 3 located in the display region AA and the heating wires 3 located in the non-display region NA are also differentially disposed. In an embodiment, in the same area, the resistance of the heating wires 3 in the non-display region NA may be made greater than the resistance of the heating wires 3 in the display region AA. The same area may also be understood as a unit area, and the specific value is not limited. The same area may refer to an area of a certain region in the extension direction of the display panel 1. In the same area, the resistance of heating wires 3 refers to the total resistance of all heating wires 3 in a region of a certain area, that is, the resistance value of the heating wires 3.

It is to be understood that when the display panel 1 is heated by the heating wires 3, a current or voltage is applied to the heating wires 3 so that the heating wires 3 generate heat. The heating wires 3 may be regarded as heating conducting wires. According to the calculation formula of conductor power, the power P=I²R, I denotes the current passing through a resistor, and R denotes the magnitude of resistance. That is, when the current passing through the heating wires 3 is constant, heating power is positively correlated with the resistance of the heating wires 3. In the same area, the greater the resistance of the heating wires 3 is, the greater the heating power is. Thus, in this embodiment of the present application, the resistance of the heating wires 3 in the non-display region NA is configured to be greater than the resistance of the heating wires 3 in the display region AA. In this manner, the heating effect of the heating wires 3 on the non-display region NA of a certain area is stronger than the heating effect of the heating wires 3 on the display region AA of the same area. Thus, the heating effect on the non-display region NA of the display panel 1 is improved, and the problem of fast heat dissipation of the non-display region NA is made up. The heating effect of the heating wires 3 on different regions of the display panel 1 matches the heating requirements of the regions, so that the temperatures of the display region AA and the non-display region NA of the display panel 1 are relatively consistent. Moreover, it is ensured that the temperature of each region of the display panel 1 is maintained in the normal working temperature range of liquid crystal molecules.

It is to be noted that in the drawings of this embodiment of the present application, merely the heating wires 3 are shown. In the actual application process, a heating circuit is formed between any one or more heating wires 3. Two ends of the heating circuit are provided with heating terminals (not shown). A heating chip (not shown) supplies a current or voltage to the heating circuit through the heating terminals.

The specific arrangement and specific structure parameter of the heating wires 3 are not limited in this embodiment of the present application, and those skilled in the art may configure them according to actual requirements. It is ensured that in the same area, the resistance of heating wires 3 located in the non-display region NA is higher than the resistance of heating wires 3 located in the display region AA. In the embodiment shown in FIGS. 5 and 6, the display panel 1 may include pixel units 6 arranged in an array in a first direction X and the second direction Y Multiple heating wires 3 may extend along the first direction X and be arranged in the second direction Y The heating wires 3 extend to the display region AA and the non-display region NA in the first direction X, and the actual arrangement is not limited thereto.

In other embodiments not shown in the present application, multiple heating wires 3 may extend along the second direction Y and be arranged in the first direction X. The heating wires 3 extend to the display region AA and the non-display region NA in the second direction Y Alternatively, multiple heating wires 3 are grid-shaped in the first direction X and the second direction Y The heating wires 3 extend to the display region AA and the non-display region NA in both the first direction X and the second direction Y to heat the display region AA and the non-display region NA.

Those skilled in the art may configure the specific structure of the backlight module 2 and other film structures in the display panel 1 according to actual requirements. As shown in FIG. 4, the display panel 1 may include an array substrate 11, a liquid crystal layer 12, and an opposing substrate 13 stacked in sequence in the thickness direction of the display panel 1. The array substrate 11 is adjacent to the backlight module 2. The array substrate 11 is provided with a pixel driving circuit (not shown). The pixel driving circuit is configured to drive the liquid crystal molecules to deflect, so that the display panel 1 emits light. The opposing substrate 13 may be a color filter substrate and mainly configured to filter light to implement color display. The specific disposition of the preceding film structure may be set by those skilled in the art according to actual requirements, and this is not limited or repeated in detail in this embodiment of the present application.

The display panel provided by this embodiment of the present application includes a display region and a non-display region. At least part of the non-display region is configured to be attached to the backlight module. The display panel also includes multiple heating wires located in the display region and the non-display region. The heating wires may heat the display region and the non-display region of the display panel to ensure the overall heating effect of the display panel. In addition, in the present application, in the same area, the resistance of the heating wires located in the non-display region is also configured to be greater than the resistance of the heating wires located in the display region. Thus, the heating effect on the non-display region of the display panel is enhanced to make up for the problem of fast heat dissipation of the non-display region. In this manner, the temperatures of the display region and the non-display region of the display panel are relatively consistent. Moreover, it is ensured that the temperature of each region of the display panel is maintained in the normal working temperature range of liquid crystal molecules.

Optionally, FIG. 7 is an enlarged view illustrating another structure of part B of FIG. 5. Further referring to FIGS. 6 and 7, in an optional embodiment, the heating wires 3 includes first heating wires 31 and second heating wires 32. The first heating wires 31 are located in the display region AA. The second heating wires 32 are located in the non-display region NA. In the same area, the length of second heating wires 32 is greater than the length of first heating wires 31 (as shown in FIG. 6). Moreover/Alternatively, the width of a second heating wire 32 is smaller than the width of a first heating wire 31 (as shown in FIG. 7).

In an embodiment, as shown in FIGS. 6 and 7, a first heating wire 31 and a second heating wire 32 may be connected to each other to form an integrated heating wire 3. The first heating wire 31 is the part of the heating wire 3 located in the display region AA, and the second heating wire 32 is the part of the heating wire 3 located in the non-display region NA. Thus, the first heating wire 31 and the second heating wire 32 may share one heating terminal (not shown), thereby saving the space of the display panel 1 and simplifying the wiring structure. At the same time, it is also possible to avoid the problem of a heavy load of a heating chip (not shown) due to excessive heating terminals.

The drive mode of the heating wires 3 may be driven in a constant-current or constant-voltage manner. Those skilled in the art may configure the drive mode according to actual requirements, and this is not limited or repeated in detail in this embodiment of the present application.

Further, the calculation formula of conductor resistance is: resistance R=ρL/S. ρ denotes the resistivity of the conductor and is determined by the property of the conductor. L denotes the length of a resistor. S denotes the cross-section area of the resistor. According to this formula, when the resistivity p is constant, the resistance of the conductor is proportional to the length of the conductor and inversely proportional to the cross-section area of the conductor. Thus, in this embodiment, in the same area, the length of the second heating wires 32 may be increased and/or the width of a second heating wire 32 may be reduced to increase the resistance of the second heating wires 32 in the same area.

For example, with respect to the solution in which the length of the second heating wires 32 is increased in the same area, the first heating wires 31 may be configured to extend along a straight line in the display region AA, and the second heating wires 32 may be configured to extend in a bending manner in the non-display region NA.

In an embodiment, further referring to FIG. 6, the second heating wires 32 in the non-display region NA may be configured to have a bending structure, and the first heating wires 31 in the display region AA may be configured to have a straight-line structure. Thus, in the same area, the length of the bending second heating wires 32 is necessarily greater than the length of the straight second heating wires 32. In this configuration, the preparation technique of the heating wires 3 in the display region AA is relatively simple. The width of a heating wire 3 in the display region AA and the width of a heating wire 3 in the non-display region NA are the same, so that the connection effect of the first heating wires 31 and the second heating wires 32 can be ensured.

The bending shape of the second heating wires 32 is not limited and may be a curved bending shape, a serpentine bending shape, or a polyline bending shape, but is not limited thereto.

In the embodiment shown in FIG. 7, the width of a second heating wire 32 extending to the non-display region NA is reduced, thereby reducing the cross-section area of the second heating wire 32. In this manner, under the same length, the resistance of second heating wires 32 is higher than the resistance of first heating wires 31. In this configuration, both the preparation technique of the heating wires 3 in the display region AA and the preparation technique of the heating wires 3 in the non-display region NA are relatively simple, and the overall preparation difficulty of the heating wires 3 can be reduced.

In other embodiments, the second heating wires 32 may be configured to extend in a bending manner, and the first heating wires 31 may be configured to extend along a straight line. Moreover, the width of a second heating wire 32 is smaller than the width of a first heating wire 31. Thus, the heating effect of the heating wires 3 on the non-display region NA may be greatly improved, and the problem of faster heat dissipation in the non-display region NA is alleviated.

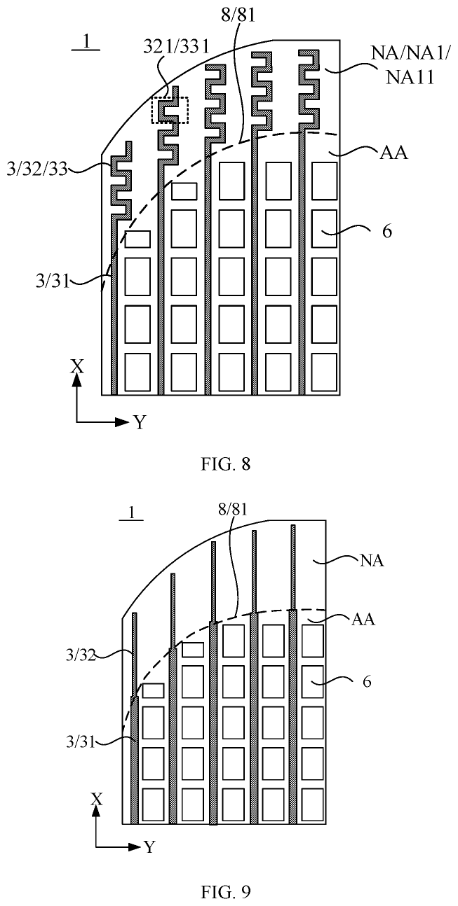

The regions shown in FIGS. 6 and 7 show the arrangement of heating wires 3 in the display region AA and its peripheral regular non-display region. FIGS. 8 and 9 are two enlarged partial views illustrating the structures of two display panels at part C of FIG. 5. FIGS. 8 and 9 each show the arrangements of heating wires 3 in the display region AA and its peripheral irregular non-display region. Referring to FIGS. 8 and 9, in the irregular non-display region, the heating wires 3 still satisfy the preceding design method.

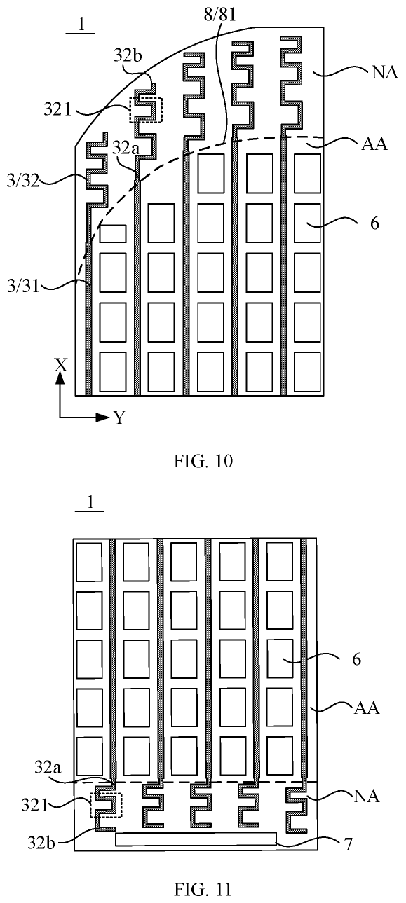

Optionally, FIG. 10 is an enlarged partial view illustrating the structure of a display panel according to an embodiment of the present application. Referring to FIG. 10, in an optional embodiment, a second heating wire 32 includes at least one second bending unit 321. The density of the second bending units 321 gradually increases in the extension direction of the second heating wire 32. The extension direction of the second heating wire 32 is a direction from a first end 32a of the second heating wire 32 close to the display region AA to a second end 32b of the second heating wire 32 away from the display region AA.

In an embodiment, as shown in FIG. 10, the second heating wire 32 may be composed of one or more bending units. The bending units constituting the second heating wire 32 may be defined as second bending units 321. The extension direction of the second heating wire 32 is parallel to the first direction X. In the orientation shown in FIG. 10, the first direction X is the extension direction of the second heating wire 32, that is, a direction where the first end 32a of the second heating wire 32 points to the second end 32b. In the direction where the first end 32a points to the second end 32b, the second heating wire 32 gradually approaches the outer edge of the display panel 1.

Further, in this embodiment, in the direction where the first end 32a points to the second end 32b, the arrangement density of second bending units 321 gradually increases. Thus, the arrangement density of the second bending units 321 close to the outer edge of the display panel 1 is greater, and the arrangement density of the second bending units 321 close to the display region AA is smaller.

It is to be understood that the outer edge of the display panel 1 is more close to the external environment. When the temperature of the external environment is lower, the more close to the outer edge of the display panel 1 is, the faster the heat dissipation rate of the display panel 1 is. Based on this, in this embodiment, in the direction where the first end 32a of the second heating wire 32 points to the second end 32b, the arrangement density of second bending units 321 is configured to gradually increase. Thus, in the first direction X, the resistance of second heating wires 32 per unit area gradually increases, thereby enhancing the heating effect on the edge of the display panel 1 and better maintaining the temperature of the edge of the display panel 1.

Optionally, FIG. 11 is an enlarged partial view illustrating the structure of another display panel according to an embodiment of the present application. Referring to FIG. 11, in an optional embodiment, a second heating wire 32 may include at least one second bending unit 321. The density of the second bending units 321 gradually decreases in the extension direction of the second heating wire 32. The extension direction of the second heating wire 32 is the direction from the first end 32a of the second heating wire 32 close to the display region AA to the second end 32b of the second heating wire 32 away from the display region AA. The display panel 1 also includes a drive module 7 located in the non-display region NA. The drive module 7 is located on the side of at least part of the second heating wires 32 away from the display region AA.

In an embodiment, in the embodiment shown in FIG. 11, the drive module 7 may be disposed on the side of the second heating wires 32 away from the display region AA, that is, the drive module 7 is more close to the second end 32b of a second heating wire 32. The drive module 7 may include a driver chip and/or a heating chip. The driver chip is configured to provide a signal required for display to the pixel units 6 in the display panel 1. The heating chip is configured to provide a signal required for heating to the heating wires 3. The heating chip and the driver chip may be disposed separately, or the heating chip may be integrally with the driver chip. This is not limited in this embodiment of the present application.

It is to be understood that during the display of the display panel 1, since the drive module 7 is continuously in a working state, the drive module 7 generates heat, so that there is a heat source at the second end 32b of the second heating wire 32. In this configuration, in the display panel 1, the rate of heat dissipation of the region close to the second end 32b of the second heating wire 32 may be lower than the rate of heat dissipation of the region close to the first end 32a of the second heating wire 32 (that is, the region close to display region AA). Based on this, the change rule of the arrangement density of the second bending units 321 in this embodiment may be configured to be opposite to the change rule of the arrangement density of the second bending units 321 of the embodiment shown in FIG. 10. That is, in this embodiment, in the direction where the first end 32a of the second heating wire 32 points to the second end 32b, the arrangement density of second bending units 321 gradually decreases. Thus, in this direction, the resistance of second heating wires 32 per unit area gradually decreases. In this manner, the heating effect of the heating wires 3 on the part of the non-display region NA that is close to the display region AA is improved, and the heating effect of the heating wires 3 on the part of the non-display region NA that is close to the drive module 7 is appropriately reduced. Thus, the consistency of the temperatures of different regions of the display panel 1 is maintained.

In the embodiment shown in FIGS. 10 and 11, the width of a second heating wire 32 is smaller than the width of a first heating wire 31, but is not limited to this in practice. In other embodiments, the width of the second heating wire 32 may be equal to the width of the first heating wire 31.

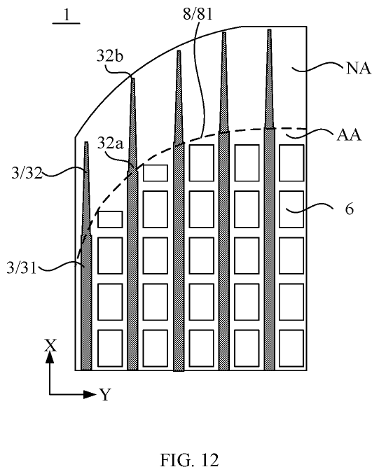

Accordingly, FIG. 12 is an enlarged partial view illustrating the structure of another display panel according to an embodiment of the present application. Referring to FIG. 12, in an optional embodiment, the width of a second heating wire 32 gradually decreases in the extension direction of the second heating wire 32. The extension direction of the second heating wire 32 is the direction from the first end 32a of the second heating wire 32 close to the display region AA to the second end 32b of the second heating wire 32 away from the display region AA.

In an embodiment, in the direction where the first end 32a of the second heating wire 32 points to the second end 32b, the width of the second heating wire 32 may be gradually reduced. Thus, in this direction, the resistance of second heating wires 32 per unit area gradually increases, thereby increasing the heating effect of the second heating wires 32 at the outer edge of the display panel 1 and better maintaining the temperature of the edge of the display panel 1.

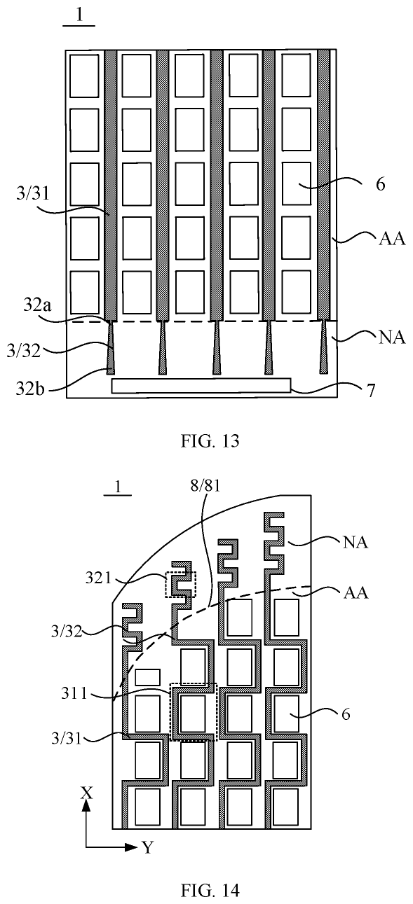

FIG. 13 is an enlarged partial view illustrating the structure of another display panel according to an embodiment of the present application. In the embodiment shown in FIG. 13, the width of a second heating wire 32 gradually increases in the extension direction of the second heating wire 32. The extension direction of the second heating wire 32 is the direction from the first end of the second heating wire 32 close to the display region AA to the second end of the second heating wire 32 away from the display region AA. The display panel 1 also includes a drive module 7 located in the non-display region NA. The drive module 7 is located on the side of at least part of the second heating wires 32 away from the display region AA.

The disposition of the drive module 7 in this embodiment is the same as the disposition of the drive module 7 of the embodiment shown in FIG. 11. Based on the disposition position of the drive module 7, in the direction where the first end 32a of the second heating wire 32 points to the second end 32b, the width of the second heating wire 32 may gradually increase. Thus, in this direction, the resistance of second heating wires 32 per unit area gradually decreases. In this manner, the heating effect of the heating wires 3 on the part of the non-display region NA that is close to the display region AA is improved, and the heating effect of the heating wires 3 on the part of the non-display region NA that is close to the drive module 7 is appropriately reduced. Thus, the consistency of the temperatures of different regions of the display panel 1 is maintained.

It is to be noted that in the embodiment shown in FIGS. 12 and 13, for example, the second heating wires 32 extend along a straight line. When the second heating wires 32 extend in a bending manner as shown in FIG. 6, the gradient scheme of the width of the second heating wire 32 may be set as described above, and this is not described in detail in this embodiment of the present application.

Optionally, FIG. 14 is an enlarged partial view illustrating the structure of another display panel according to an embodiment of the present application. Referring to FIG. 14, in an optional embodiment, the first heating wires 31 may be configured to extend in a bending manner in the display region AA, and the second heating wires 32 may be configured to extend in a bending manner in the non-display region NA. The first heating wires 31 include multiple first bending units 311, and the second heating wires 32 include multiple second bending units 321. In the same area, the density of first bending units 311 is smaller than the density of second bending units 321.

In an embodiment, as shown in FIG. 14, in this embodiment, the first heating wires 31 and the second heating wires 32 may be configured to extend in a bending manner. A first heating wire 31 is composed of one or more first bending units 311. A second heating wire 32 is composed of one or more second bending units 321. At this time, to ensure that in the same area, the resistance of the second heating wires 32 is higher than the resistance of the first heating wires 31, in the same area, the arrangement density of the second bending units 321 in the non-display region NA may be configured to be greater than the arrangement density of the first bending units 311 in the display region AA. Further, it is ensured that the second heating wires 32 have a strong heating effect on the non-display region NA, and the uniformity of the temperatures of different regions of the display panel 1 is maintained.

In addition, it is to be noted that in the embodiment shown in FIG. 14, a first bending unit 311 is bent around a pixel unit 6. The disposition manner of the first bending unit 311 is only an example, but is not limited to this in practice. Those skilled in the art may adjust the disposition of the first bending unit 311 according to actual conditions.

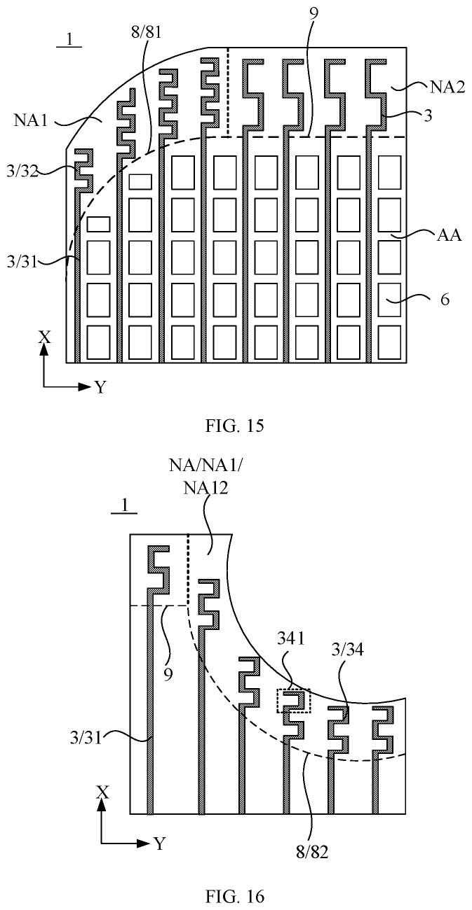

Optionally, FIG. 15 is an enlarged partial view illustrating the structure of another display panel according to an embodiment of the present application. Referring to FIG. 15, in an optional embodiment, the display region AA includes an irregular edge 8 and a regular edge 9. The irregular edge 8 may include an arc edge. The regular edge 9 may include a straight edge. The non-display region NA includes a first non-display region NA1 and a second non-display region NA2. The first non-display region NA1 is located on the side of the irregular edge 8 facing away from the display region AA. The second non-display region NA2 is located on the side of the regular edge 9 facing away from the display region AA. In the same area, the resistance of heating wires 3 located in the first non-display region NA1 is higher than the resistance of heating wires 3 located in the second non-display region NA2.

In an embodiment, as shown in FIGS. 5 and 15, in this embodiment, the display panel 1 may be an irregular display panel 1. Accordingly, a display region edge includes an irregular edge 8 and a regular edge 9. The regular edge 9 may extend along a straight line, and the irregular edge 8 may extend along a curve line, and in particular may extend along an arc. The display region edge is configured to separate the display region AA from the non-display region NA. In an embodiment, the irregular edge 8 is configured to separate the display region AA from the first non-display region NA1, and the regular edge 9 is configured to separate the display region AA from the second non-display region NA2.

It is to be understood that since the irregular edge 8 extends in an arc, and the regular edge 9 extends in a straight line, two points are taken on the irregular edge 8, and the extension length of the irregular edge 8 between the two points is greater than the straight-line distance between the two points; and similarly, two points are taken on the regular edge 9, and the extension length of the regular edge 9 between the two points is equal to the straight-line distance between the two points. At this time, a certain length in the extension direction of the display region edge is used as a long side, and a certain length in the direction perpendicular to the long side is used as a short side to form a graphic. Under the area corresponding to the graphic, the extension length of the irregular edge 8 is longer than the extension length of the regular edge 9. As the extension length of the display region edge increases, the contact area between the non-display region NA and the external environment and/or the backlight module 2 increases. That is, the rate of heat dissipation of the first non-display region NA1 corresponding to the irregular edge 8 is greater than the rate of heat dissipation of the second non-display region NA2 corresponding to the regular edge 9.

Based on this, this embodiment further proposes that in the same area, the resistance of heating wires 3 located in the first non-display region NA1 may be configured to be greater than the resistance of heating wires 3 located in the second non-display region NA2. In this manner, the heating effect of the heating wires 3 on the first non-display region NA1 can be improved, so that the heating effect of the heating wires 3 on different non-display regions NA of the display panel 1 can match the heating requirements of the non-display regions NA. Further, the consistency of the temperature of each region of the display panel 1 can be ensured.

Optionally, in the same area, the length of the heating wires 3 located in the first non-display region NA1 may be configured to be greater than the length of the heating wires 3 located in the second non-display region NA2. Moreover/Alternatively, the width of a heating wire 3 located in the first non-display region NA1 may be configured to be smaller than the width of a heating wire 3 located in the second non-display region NA2. Thus, the heating wires 3 located in the first non-display region NA1 and the heating wires 3 located in the second non-display region NA2 are differentially disposed. For the implementation, reference may be made to the preceding embodiment, and the details are not repeated here. FIG. 15 illustrates that the heating wires 3 located in the second non-display region NA2 and the heating wires 3 located in the first non-display region NA1 extend in a bending manner, and that the density of the bending units of the heating wires 3 in the second non-display region NA2 is smaller than the density of the bending units of the heating wires 3 in the first non-display region NA1. Thus, the resistance of the heating wires 3 in the non-display region NA1 is increased, and the heating effect on the first non-display region NA1 is improved, which is not limited to this in practice.

FIG. 16 is an enlarged view illustrating the structure of part D of FIG. 5. Referring to FIGS. 5, 8, and 16, the irregular edge 8 includes a first irregular edge 81 and a second irregular edge 82. The connecting line between two ends of the first irregular edge 81 is located in the display region AA. The connecting line between two ends of the second irregular edge 82 is located in the non-display region NA. The first non-display region includes a first non-display sub-region NA11 and a second non-display sub-region NA12. The first non-display sub-region NA11 is located on the side of the first irregular edge 81 facing away from the display region AA. The second non-display sub-region NA12 is located on the side of the second irregular edge 82 facing away from the display region AA. The heating wires 3 include first heating wires 31, third heating wires 33, and fourth heating wires 34. The first heating wires 31 are located in the display region AA. The third heating wires 33 are located in the first non-display sub-region NA11. The fourth heating wires 34 are located in the second non-display sub-region NA12. In the same area, the resistance of third heating wires 33 is higher than the resistance of fourth heating wires 34.

In an embodiment, for some display devices having complex shapes, for example, a vehicle-mounted display device, the vehicle-mounted display device may include multiple types of irregular outer edges. As shown in FIGS. 5, 8, and 16, the irregular edge 8 of the display region AA may be divided into a first irregular edge 81 and a second irregular edge 82. The first irregular edge 81 and the second irregular 82 extend along an arc. In a direction where the center of the display panel 1 points to the first irregular edge 81, the first irregular edge 81 is a convex arc curve. In a direction where the center of the display panel 1 points to the second irregular edge 82, the second irregular edge 82 is a concave arc curve. The outside of the second irregular edge 82 may be used for placing functional elements such as an earpiece speaker (not shown), a camera (not shown), and/or various sensors (not shown) to perform functions such as photography, light sensing, and fingerprint recognition.

As shown in FIGS. 8 and 16, since the first irregular edge 81 is convex, when the heat in the first non-display sub-region NA11 is transferred outwardly, the heat is diffused in a divergent manner. Since the second irregular edge 82 is concave, when the heat is transferred outwardly in the second non-display sub-region NA12, the heat may be transferred back and forth between the second irregular edge 82. It can also be understood that the second irregular edge 82 has a certain convergence effect on the heat. Thus, normally, the rate of heat dissipation of the first non-display sub-region NA11 is faster than the rate of heat dissipation of the second non-display sub-region NA12.

Based on this, this embodiment further proposes that the heating wires 3 located in the first non-display sub-region NA11 and the heating wires 3 located in the second non-display sub-region NA12 are differentially disposed. In the same area, the resistance of third heating wires 33 located in the first non-display sub-region NA11 may be configured to be greater than the resistance of fourth heating wires 34 located in the second non-display sub-region NA12. Both the third heating wires 33 and the fourth heating wires 34 may be the second heating wires 32 in the preceding embodiments. Thus, in the same area, both the resistance of third heating wires 33 and the resistance of fourth heating wires 34 may be greater than the resistance of first heating wires 31.

In this configuration, the heating effect of the third heating wires 33 on the first non-display sub-region NA11 is stronger than the heating effect of the fourth heating wires 34 on the second non-display sub-region NA12, so that the heating effect of the heating wires 3 on different irregular non-display regions NA of the display panel 1 matches the heating requirements of the irregular non-display regions NA. Further, the consistency of the temperature of each region of the display panel 1 is ensured.

For the specifically differential disposition of the resistance of the third heating wires 33 and the resistance of the fourth heating wires 34, reference may be made to the preceding embodiment. For example, further referring to FIGS. 8 and 16, in an optional embodiment, in the same area, the length of third heating wires 33 is greater than the length of fourth heating wires 34. Moreover/Alternatively, the width of a third heating wire 33 is smaller than the width of a fourth heating wire 34.

Same as the preceding embodiments, in the same area, the length of the third heating wires 33 may be increased and/or the width of a third heating wire 33 may be reduced to increase the resistance of the second heating wires 32 per unit area. In FIGS. 8 and 16, the length of third heating wires 33 per unit area may be increased to increase the resistance of the third heating wires 33. The difference between the width of a third heating wire 33 and the width of a fourth heating wire 34 is not shown.

For example, in an optional embodiment, further referring to FIGS. 8 and 16, the first heating wires 31 may be configured to extend along a straight line in the display region AA, the third heating wires 33 extend in a bending manner in the first non-display sub-region NA11, and the fourth heating wires 34 extend in a bending manner in the second non-display sub-region NA12. A third heating wire 33 includes at least one third bending unit 331. A fourth heating wire 34 includes at least one fourth bending unit 341. In the same area, the density of the third bending units 331 is greater than the density of the fourth bending units 341.

In an embodiment, as shown in FIGS. 8 and 16, the first heating wires 31 still extend along a straight line. The third heating wires 33 and the fourth heating wires 34 extend in a bending manner. A third heating wire 33 is composed of one or more third bending units 331. A fourth heating wire 34 is composed of one or more fourth bending units 341. At this time, to ensure that in the same area, the resistance of third heating wires 33 is higher than the resistance of fourth heating wires 34, in the same area, the arrangement density of third bending units 331 in the first non-display sub-region NA11 may be configured to be greater than the arrangement density of fourth bending units 341 in the second non-display sub-region NA12. Further, it is ensured that the third heating wires 33 have a strong heating effect on the first non-display sub-region NA11.

In addition to the preceding embodiments, this embodiment of the present application proposes several embodiments below for reducing the resistance of the fourth heating wires 34.

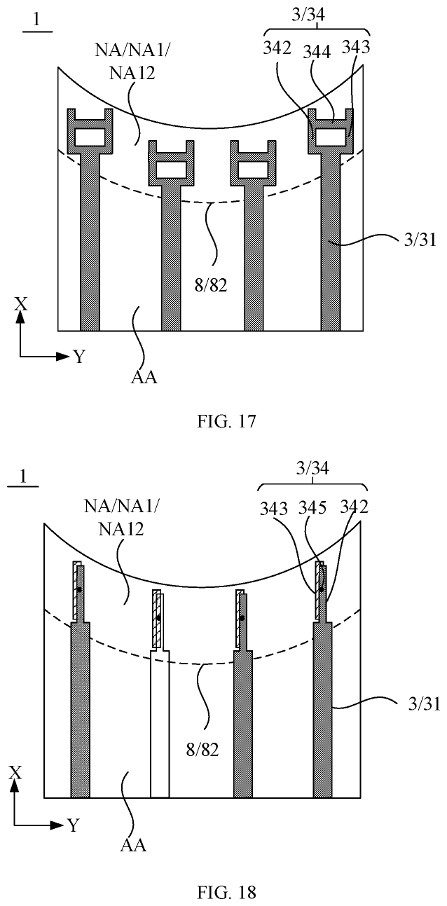

For example, FIGS. 17 and 18 are another two enlarged partial views illustrating the structures of a display panel according to an embodiment of the present application. FIG. 17 and FIG. 18 show the second non-display sub-region NA12 of the display panel 1. Referring to FIGS. 17 and 18, in an optional embodiment, a fourth heating wire 34 includes a first subsection 342 and a second subsection 343. The first subsection 342 and the second subsection 343 are connected in parallel.

In an embodiment, those skilled in the art know that the total resistance of two conductors connected in parallel is smaller than the resistance of either conductor. Based on this, as shown in FIGS. 17 and 18, a fourth heating wire 34 is configured to be composed of a first subsection 342 and a second subsection 343 connected in parallel. Thus, the resistance of each fourth heating wire 34 is reduced. In this embodiment, a third heating wire 33 may be disposed in the same manner as the first subsection 342 or the second subsection 343, so that in the same area, the resistance of fourth heating wires 34 is smaller than the resistance of third heating wires 33. Further, it is ensured that the overall heating effect of the fourth heating wires 34 on the second non-display sub-region NA12 is weaker than the heating effect of the third heating wires 33 on the first non-display sub-region NA11.

For example, further referring to FIGS. 17 and 18, the first subsection 342 and the second subsection 343 are disposed in the same layer and connected in parallel through a parallel subsection 344. Alternatively, the first subsection 342 and the second subsection 343 are in different layers and connected in parallel through a via 345.

In an embodiment, FIGS. 17 and 18 show two parallel connection modes of the first subsection 342 and the second subsection 343. In the embodiment shown in FIG. 17, the first subsection 342 and the second subsection 343 are disposed in the same film of the display panel 1. The two are connected through the parallel subsection 344 also located in this film. Thus, the first subsection 342, the second subsection 343, and the parallel subsection 344 may be formed in the same manufacturing process, thereby simplifying the preparation method of the fourth heating wires 34.

In the embodiment shown in FIG. 18, the first subsection 342 and the second subsection 343 are disposed in different films of the display panel 1. The two are connected in parallel through the via 345. Thus, it is possible to reduce the area occupied by the first subsection 342 and the area occupied by the second subsection 343 in the extension direction of the plane where the display panel 1 is located may be reduced.

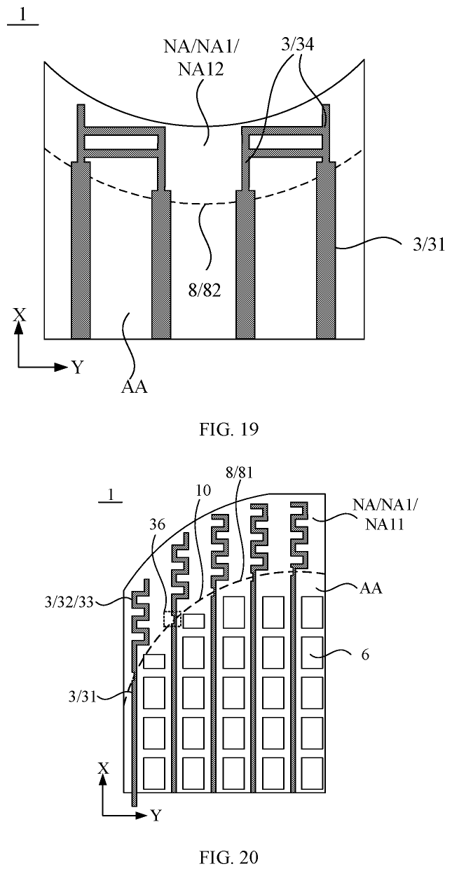

For example, FIG. 19 is an enlarged partial view illustrating the structure of another display panel according to an embodiment of the present application. Referring to FIG. 19, in another optional embodiment, two adjacent fourth heating wires 34 may be configured to be connected in parallel. Optionally, in this embodiment, two adjacent fourth heating wires 34 may be directly connected in parallel, thereby reducing the resistance of the fourth heating wires 34.

Optionally, FIG. 20 is an enlarged partial view illustrating the structure of another display panel according to an embodiment of the present application. Referring to FIG. 20, in an optional embodiment, the display region AA includes a display region edge 10 that separates the display region AA from the non-display region NA. A first heating wire 31 is connected to a second heating wire 32. The projection of the connection region 36 of the first heating wire 31 and the second heating wire 32 on the plane where the display panel 1 is located overlap the projection of the display region edge 10 on the plane where the display panel 1 is located. The width of a heating wire 3 in the connection region 36 is smaller than the width of a heating wire 3 in other regions.

Optionally, as mentioned in the preceding embodiment, the first heating wire 31 and the second heating wire 32 are connected to each other to form a heating wire 3 extending to the display region AA and non-display region NA. In a direction perpendicular to the plane where the display panel 1 is located, the connection region 36 of the first heating wire 31 and the second heating wire 32 overlaps the display region edge 10.

Since the display region AA needs to be displayed, to ensure that the liquid crystal molecules in the display region AA work normally, the heating effect of the heating wires 3 on the display region edge 10 may be configured to be greater than the heating effect of the heating wires 3 on the non-display region NA. Also, since the display region edge 10 is more close to the outer edge of the display panel 1 than the display region AA, the heating effect of the heating wires 3 on the display region edge 10 may be configured to be greater than the heating effect of the heating wires 3 on the display region AA.

In view of the above, it is possible to further define that the width of a heating wire 3 in the connection region 36 is smaller than the width of the other part of the heating wire 3. In short, the width of a heating wire 3 in the connection region 36 is smaller than the width of the other part of the first heating wire 31 except the connection region 36 and is smaller than the width of the other part of the second heating wire 32 except the connection region 36. In this manner, under the same length, the resistance of a heating wire 3 in the connection region 36 is higher than the resistance in the other regions of the heating wire 3, thereby improving the heating effect of the heating wire 3 on the display region edge 10.

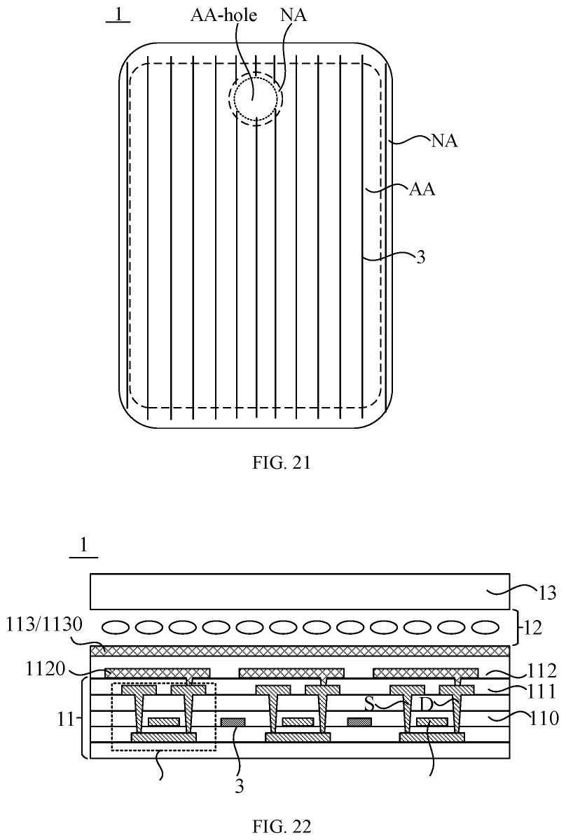

Optionally, FIG. 21 is a diagram illustrating the structure of another display panel according to an embodiment of the present application. Referring to FIGS. 5 and 21, in an optional embodiment, at least part of the non-display region NA surrounds the display region AA, and/or the display region AA surrounds at least part of the non-display region NA.

In the embodiment shown in FIG. 5, at least part of the non-display region NA surrounding the display region AA, includes the case in which the entire non-display region NA is located at the periphery of the display region AA. In the embodiment shown in FIG. 21, part of the non-display region NA may be located in the region surrounded by the edges of the display region AA. In this configuration, the non-display region NA located in the region surrounded by the display region AA corresponds to the part between an opening region AA-hole and the display region AA of the display panel 1. A hole is dug for the display panel 1 in the opening region AA-hole. Functional elements such as an earpiece speaker (not shown), a camera (not shown), and/or various sensors (not shown) may be placed in the opening region AA-hole to perform functions such as photography, light sensing, and fingerprint recognition. The non-display region NA between the opening region AA-hole and the display region AA may also be generally attached to and fixed to the backlight module (not shown in FIG. 21). Similarly, there may also be a problem that the rate of heat dissipation of the non-display region NA is greater than the rate of heat dissipation of the display region AA, which is also applicable to the solution in the present application.

Optionally, in an optional embodiment, FIG. 22 is a sectional view illustrating the structure of a display panel according to an embodiment of the present application. Referring to FIG. 22, the display panel 1 also includes a gate metal layer 110, a source and drain metal layer 111, a pixel electrode layer 112, and a common electrode layer 113. The heating wires 3 are formed in any one or more of the gate metal layer 110, the source and drain metal layer 111, the pixel electrode layer 112, and the common electrode layer 113.

As described in the preceding embodiments, the display panel 1 may include the array substrate 11. The pixel driving circuit in the array substrate 11 may include at least one transistor T. The display panel 1 may also be provided with a pixel electrode layer 112 and a common electrode layer 113. The pixel electrode layer 112 may include multiple independent pixel electrodes 1120. The common electrode layer 113 may include multiple common electrodes 1130. In the thickness direction of the display panel 1, the pixel electrodes 1120 may or may not overlap the common electrodes 1130. The common electrode layer 113 may be a common layer, but is not limited thereto.

As shown in FIG. 22, the transistor T may be electrically connected to a pixel electrode 1120. When the transistor T is turned on, an electrical signal is transmitted to the pixel electrode 1120. At the same time, while the drive module 7 transmits another electrical signal to a common electrode 1130. An electric field is formed between the pixel electrode 1120 and the common electrode 1130, so that the liquid crystal molecules in the range of the electric field are driven to deflect. The pixel electrode 1120 and the common electrode 1130 may be located on the same side of the liquid crystal layer 12 or on opposite sides of the liquid crystal layer 12. This is not limited in this embodiment of the present application and may be set by those skilled in the art according to actual requirements. As shown in FIG. 22, the pixel electrode 1120 and the common electrode 1130 may be located on the same side of the liquid crystal layer 12 to form a boundary electric field switching display panel. In this configuration, the display panel 1 may have a relatively great display viewing angle. In addition, as shown in FIG. 22, the common electrode 1130 is located between the pixel electrode 1120 and the liquid crystal layer 12, but is not limited to this in practice. In other embodiments, the pixel electrode 1120 may be configured to be located between the common electrode 1130 and the liquid crystal layer 12.

The transistor T may include a gate G, a source S, and a drain D. The gate G may be connected to a scan signal line (not shown). The source S (drain D) may be connected to a data signal line (not shown). The drain D (source S) may be connected to the pixel electrode 1120. Each of the preceding gate G, source S, drain D, pixel electrode 1120, and common electrode 1130 may be made of a metal material. The gate G may be formed in the gate metal layer 110. The source S and the drain D may be formed in the source and drain metal layer 111. In the present application, the heating wires 3 may be formed in any one or more layers of the preceding metal layers. Thus, a metal layer where the heating wires 3 are located does not need to be additionally prepared to ensure that the display panel 1 has a relatively thin thickness.

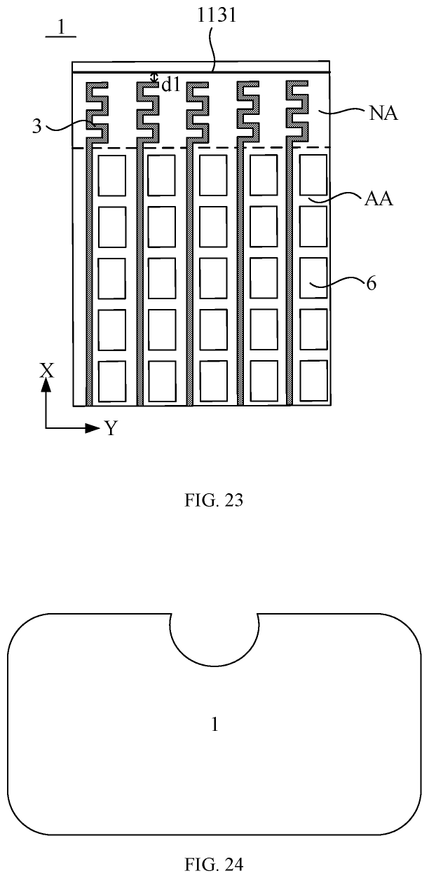

Optionally, FIG. 23 is an enlarged partial view illustrating the structure of another display panel according to an embodiment of the present application. Referring to FIG. 23, in an optional embodiment, the display panel 1 also includes a first signal transmission line 1131. At least part of the first signal transmission line 1131 is located in the non-display region NA. The spacing dl between the projection of a heating wire 3 located in the non-display region NA on the plane where the display panel 1 is located and the projection of the first signal transmission line 1131 on the plane where the display panel 1 is located is greater than or equal to a preset spacing threshold.

In an embodiment, as shown in FIG. 23, the first signal transmission line 1131 may be any signal transmission line in the non-display region NA, such as a common electrode bus, but is not limited thereto. The drive module 7 transmits a voltage signal to the common electrode 1130 through the common electrode bus. Since part of the first signal transmission line 1131 and heating wires 3 are located in the non-display region NA, to avoid coupling of the voltage signals transmitted by the two signal wires and increasing of signal transmission impedance, in this embodiment, in the extension direction of the plane where the display panel 1 is located, the spacing dl between the first signal transmission line 1131 and a heating wire 3 close to the first signal transmission line 1131 may be configured to be greater than or equal to a preset spacing threshold, thereby ensuring normal transmission of the voltage signals in the two signal wires.

The specific value of the preset spacing threshold is not limited. Those skilled in the art may set it according to the arrangement of signal transmission lines in the non-display region NA in the practical application. This is not described in detail in the present application.

Based on the same concept, an embodiment of the present application provides a display device. FIG. 24 is a top view illustrating the structure of a display device according to an embodiment of the present application. Referring to FIGS. 4 and 24, the display device includes the display panel 1 provided by any embodiment of the present application and a backlight module 2. The backlight module 2 is located on the side of the display panel 1 facing away from the light-emitting side of the display panel 1. The backlight module 2 is attached to and fixed to at least part of the non-display region NA of the display panel 1. The display device according to this embodiment of the present application has all the technical features and the beneficial effects of the display panel 1 according to any embodiment of the present application, and the details are not repeated here. For example, the display device may be an electronic device such as an in-vehicle display, a computer, a smart wearable device (such as a smart watch), and a mobile phone device. This is not limited in this embodiment of the present application.

As shown in FIG. 24, the groove region of the display device may be used for placing functional elements such as an earpiece speaker (not shown), a camera (not shown), and/or various sensors (not shown) to perform functions such as photography, light sensing, and fingerprint recognition. For example, the display device is a vehicle-mounted display device. A camera may be placed in the groove region of the vehicle-mounted display device to acquire the image information of a driver or a passenger, thereby improving driving safety.

It is to be noted that the preceding are only preferred embodiments of the present application and the technical principles used therein. It is to be understood by those skilled in the art that the present application is not limited to the embodiments described herein. For those skilled in the art, various apparent modifications, adaptations, combinations, and substitutions can be made without departing from the scope of the present application. Therefore, while the present application is described in detail in connection with the preceding embodiments, the present application is not limited to the preceding embodiments and may include equivalent embodiments without departing from the concept of the present application. The scope of the present application is determined by the scope of the appended claims.

What is claimed is:

1. A display panel, comprising a display region and a non-display region, wherein at least part of the non-display region is configured to be attached to a backlight module; and
the display panel further comprises a plurality of heating wires located in the display region and the non-display region, wherein in a same area, resistance of heating wires located in the non-display region is higher than resistance of heating wires located in the display region.

2. The display panel according to claim 1, wherein the plurality of heating wires comprise first heating wires and second heating wires, the first heating wires are located in the display region, and the second heating wires are located in the non-display region; and
at least one of the following applies: in a same area, a length of second heating wires of the second heating wires is greater than a length of first heating wires of the first heating wires, or a width of a second heating wire of the second heating wires is smaller than a width of a first heating wire of the first heating wires.

3. The display panel according to claim 2, wherein the first heating wires extend along a straight line in the display region, and the second heating wires extend in a bending manner in the non-display region.

4. The display panel according to claim 3, wherein a second heating wire of the second heating wires comprises at least one second bending unit, and density of the at least one second bending unit gradually increases in an extension direction of the second heating wire; and the extension direction of the second heating wire is a direction from a first end of the second heating wire close to the display region to a second end of the second heating wire away from the display region.

5. The display panel according to claim 3, wherein a second heating wire of the second heating wires comprises at least one second bending unit, and density of the at least one second bending unit gradually decreases in an extension direction of the second heating wire; and the extension direction of the second heating wire is a direction from a first end of the second heating wire close to the display region to a second end of the second heating wire away from the display region; and
the display panel further comprises a drive module located in the non-display region, and the drive module is located on a side of at least part of the second heating wires away from the display region.

6. The display panel according to claim 3, wherein a width of a second heating wire of the second heating wires gradually decreases in an extension direction of the second heating wire; and the extension direction of the second heating wire is a direction from a first end of the second heating wire close to the display region to a second end of the second heating wire away from the display region.

7. The display panel according to claim 3, wherein a width of a second heating wire of the second heating wires gradually increases in an extension direction of the second heating wire; and the extension direction of the second heating wire is a direction from a first end of the second heating wire close to the display region to a second end of the second heating wire away from the display region; and
the display panel further comprises a drive module located in the non-display region, and the drive module is located on a side of at least part of the second heating wires away from the display region.

8. The display panel according to claim 2, wherein the first heating wires extend in a bending manner in the display region, and the second heating wires extend in a bending manner in the non-display region; and
the first heating wires comprise a plurality of first bending units, the second heating wires comprise a plurality of second bending units, and in a same area, density of first bending units is smaller than density of second bending units.

9. The display panel according to claim 1, wherein the display region comprises an irregular edge and a regular edge, the irregular edge comprises an arc edge, and the regular edge comprises a straight edge;
the non-display region comprises a first non-display region and a second non-display region, the first non-display region is located on a side of the irregular edge facing away from the display region, and the second non-display region is located on a side of the regular edge facing away from the display region; and
in a same area, resistance of heating wires located in the first non-display region is higher than resistance of heating wires located in the second non-display region.

10. The display panel according to claim 9, wherein the irregular edge comprises a first irregular edge and a second irregular edge, a connecting line between two ends of the first irregular edge is located in the display region, and a connecting line between two ends of the second irregular edge is located in the non-display region;
the first non-display region comprises a first non-display sub-region and a second non-display sub-region, the first non-display sub-region is located on a side of the first irregular edge facing away from the display region, and the second non-display sub-region is located on a side of the second irregular edge facing away from the display region;
the plurality of heating wires comprise first heating wires, third heating wires, and fourth heating wires, the first heating wires are located in the display region, the third heating wires are located in the first non-display sub-region, and the fourth heating wires are located in the second non-display sub-region; and
in a same area, resistance of third heating wires of the third heating wires is higher than resistance of fourth heating wires of the third heating wires.

11. The display panel according to claim 10, wherein at least one of the following applies:
in a same area, a length of third heating wires of the third heating wires is greater than a length of fourth heating wires of the fourth heating wires, or a width of a third heating wire of the third heating wires is greater than a width of a fourth heating wire of the fourth heating wires.

12. The display panel according to claim 11, wherein the first heating wires extend along a straight line in the display region, the third heating wires extend in a bending manner in the first non-display sub-region, and the fourth heating wires extend in a bending manner in the second non-display sub-region; and
a third heating wire of the third heating wires comprises at least one third bending unit, a fourth heating wire of the fourth heating wires comprises at least one fourth bending unit, and in a same area, density of the at least one third bending unit is greater than density of the at least one fourth bending unit.

13. The display panel according to claim 10, wherein a fourth heating wire of the fourth heating wires comprises a first subsection and a second subsection, and the first subsection and the second subsection are connected in parallel.

14. The display panel according to claim 13, wherein the first subsection and the second subsection are disposed in a same layer and connected in parallel through a parallel subsection; or
the first subsection and the second subsection are in different layers and connected in parallel through a via.

15. The display panel according to claim 10, wherein two adjacent fourth heating wires of the fourth heating wires are connected in parallel.

16. The display panel according to claim 2, wherein the display region comprises a display region edge that separates the display region from the non-display region; and
one of the first heating wires is connected to one of the second heating wires, a projection of a connection region of the one first heating wire and the one second heating wire on a plane where the display panel is located overlap a projection of the display region edge on the plane where the display panel is located, and a width of a heating wire in the connection region is smaller than a width of a heating wire in other regions.

17. The display panel according to claim 1, wherein at least one of the following applies:
at least part of the non-display region surrounds the display region, or the display region surrounds at least part of the non-display region.

18. The display panel according to claim 1, further comprising a gate metal layer, a source and drain metal layer, a pixel electrode layer, and a common electrode layer, and the plurality of heating wires are formed in any one or more of the gate metal layer, the source and drain metal layer, the pixel electrode layer, and the common electrode layer.

19. The display panel according to claim 1, further comprising a first signal transmission line, wherein at least part of the first signal transmission line is located in the non-display region; and
spacing between a projection of a heating wire located in the non-display region and a projection of the first signal transmission line on a plane where the display panel is located is greater than or equal to a preset spacing threshold.

20. A display device, comprising a display panel and a backlight module, wherein the backlight module is located on a side of the display panel facing away from a light-emitting side of the display panel;
wherein the display panel comprises a display region and a non-display region, wherein at least part of the non-display region is configured to be attached to a backlight module; and
the display panel further comprises a plurality of heating wires located in the display region and the non-display region, wherein in a same area, resistance of heating wires located in the non-display region is higher than resistance of heating wires located in the display region.
